(19) United States
(12) Patent Application Publication
(10) Pub. No.: US 2025/0378015 A1
(43) Pub. Date: Dec. 11, 2025

(54) MEMORY AND MEMORY CONTROLLER SUPPORTING COMMAND ADDRESS HALF RATE MODE

(71) Applicant: SK hynix Inc., Gyeonggi-do (KR)

(72) Inventors: Jung Taek YOU, Gyeonggi-do (KR); Han Byeol KWON, Gyeonggi-do (KR); Kyu Young KIM, Gyeonggi-do (KR)

(21) Appl. No.: 18/912,588

(22) Filed: Oct. 11, 2024

(30) Foreign Application Priority Data
Jun. 5, 2024 (KR) 10-2024-0073636
Jul. 18, 2024 (KR) 10-2024-0094777

(51) Int. Cl. G06F 12/02

(52) U.S. Cl. CPC G06F 12/0223

(57) ABSTRACT

A memory may include a clock receiver configured to receive clocks; a first divider configured to divide the clocks to generate divided multi-phase clocks; a second divider configured to redivide the divided multi-phase clocks to generate redivided multi-phase clocks; and a command address reception circuit configured to receive a command and an address by using the divided multi-phase clocks in a first mode, and receive the command and the address by using the redivided multi-phase clocks in a second mode.

### CROSS-REFERENCE TO RELATED APPLICATION

This patent application claims priority under 35 U.S.C. § 119 (a) to Korean Patent Application No. 10-2024-0073636 filed on Jun. 5, 2024 and Korean Patent Application No. 10-2024-0094777 filed on Jul. 18, 2024, which are incorporated herein by reference in their entirety.

### BACKGROUND

### 1. Technical Field

Embodiments of the present disclosure relate to a memory and a memory controller.

### 2. Related Art

A memory controller is a device for controlling a memory, and is configured independently or is built into various processors such as a central processing unit (CPU), a graphic processing unit (GPU), and an application processor (AP). The memory controller and memories are connected in a one-to-many manner, and various ways for connecting between the memory controllers and the memories are being studied depending on system requirements.

### SUMMARY

In an embodiment of the present disclosure, a memory may include a clock receiver configured to receive clocks; a first divider configured to divide the clocks to generate divided multi-phase clocks; a second divider configured to redivide the divided multi-phase clocks to generate redivided multi-phase clocks; and a command address reception circuit configured to receive a command and an address by using the divided multi-phase clocks in a first mode, and receive the command and the address by using the redivided multi-phase clocks in a second mode.

In an embodiment of the present disclosure, a memory controller may include a first clock terminal and a second clock terminal commonly connected to a first memory and a second memory in a first mode, and commonly connected to a third memory, a fourth memory, a fifth memory, and a sixth memory in a second mode; a plurality of command address terminals commonly connected to the first memory and the second memory in the first mode to output command address signals at a first frequency, and commonly connected to the third memory, the fourth memory, the fifth memory, and the sixth memory in the second mode to output the command address signals at a second frequency being a half of the first frequency; a first chip select terminal connected to the first memory in the first mode and commonly connected to the third memory and the fourth memory in the second mode; a second chip select terminal connected to the second memory in the first mode and commonly connected to the fifth memory and the sixth memory in the second mode; a plurality of first data terminals commonly connected to the first memory and the second memory in the first mode and commonly connected to the third memory and the fifth memory in the second mode; and a plurality of second data terminals commonly connected to the first memory and the second memory in the first mode and commonly connected to the fourth memory and the sixth memory in the second mode.

In an embodiment of the present disclosure, a memory may include a clock receiver configured to receive clocks; a divider configured to divide the clocks to generate divided multi-phase clocks; a command address reception circuit configured to receive a command and an address by using the divided multi-phase clocks; a command address decoder configured to decode the command and the address received by the command address reception circuit to generate internal command signals and internal address signals; and a latency control circuit configured to perform a latency control operation on at least one of read and write operations, in synchronization with one of the divided multi-phase clocks in a first mode, and perform the latency control operation in synchronization with the clocks in a second mode.

### BRIEF DESCRIPTION OF THE DRAWINGS

FIG. 1 is a diagram illustrating a connection between a memory controller and memories in a memory system in accordance with an embodiment of the present disclosure.

FIG. 2 is a diagram illustrating a connection between a memory controller and memories in a memory system in accordance with an embodiment of the present disclosure.

FIG. 3 is a configuration diagram of a memory in accordance with an embodiment of the present disclosure.

FIG. 4 is a configuration diagram of a memory in accordance with another embodiment of the present disclosure.

FIG. 5 is a timing diagram illustrating an operation when the memory of FIG. 4 is connected to a memory controller in the same manner as in FIG. 1 and a command address half rate mode is not set in accordance with an embodiment of the present disclosure.

FIG. 6 is a timing diagram illustrating an operation when the memory of FIG. 4 is connected to a memory controller in the same manner as in FIG. 2 and a command address half rate mode is set in accordance with an embodiment of the present disclosure.

FIG. 7 is a configuration diagram of a memory in accordance with yet another embodiment of the present disclosure.

### DETAILED DESCRIPTION

Various embodiments of the present disclosure are directed to providing a technology in which a memory stably receives a command and an address.

Embodiments of the present disclosure can provide a technology in which a memory stably receives a command and an address.

Hereafter, embodiments in accordance with the technical spirit of the present disclosure will be described with reference to the accompanying drawings.

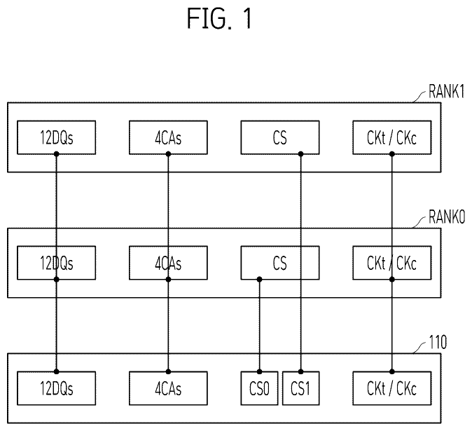

FIG. 1 is a diagram illustrating a connection between a memory controller 110 and memories RANK0 and RANK1 in a memory system in accordance with an embodiment of the present disclosure.

Referring to FIG. 1, the memory controller 110 is connected to two memories RANK0 and RANK1.

In an embodiment, the memory controller 110 includes 12 data terminals 12DQs, four command address terminals 4CAs, two chip select terminals CS0 and CS1, and clock terminals CKt and CKc.

In an embodiment, the 12 data terminals 12DQs of the memory controller 110 are commonly connected to 12 data terminals 12DQs of a first rank memory RANK0 and 12 data terminals 12DQs of a second rank memory RANK1. The four command address terminals 4CAs of the memory controller 110 are commonly connected to four command address terminals 4CAs of the rank memory RANK0 and four command address terminals 4CAs of the rank memory RANK1. The clock terminals CKt and CKc of the memory controller 110 are commonly connected to clock terminals CKt and CKc of the rank memory RANK0 and clock terminals CKt and CKc of the rank memory RANK1. A first chip select terminal CS0 of the memory controller 110 is connected to a chip select terminal CS of the rank memory RANK0, and a second chip select terminal CS1 of the memory controller 110 is connected to a chip select terminal CS of the rank memory RANK1.

In the illustrated embodiment of FIG. 1, in the rank memory RANK0 and the rank memory RANK1, the data terminals 12DQs, the command address terminals 4CAs, and the clock terminals CKt and CKc are commonly connected to the memory controller 110. However, because the chip select terminals CS of the rank memory RANK0 and the rank memory RANK1 are independently connected to the chip select terminals CS0 and CS1 of the memory controller 110, the memory controller 110 selects and independently controls one of the rank memory RANK0 and the rank memory RANK1 by using the chip select terminals CS0 and CS1.

In an embodiment, during read and write operations, the memory controller 110 may transmit and receive data with a burst length BL of 24 through the 12 data terminals 12DQs. That is, 24 bits of data is consecutively input and output for each data terminal. For example, during a read operation of the rank memory RANK0, 288 (=12*24) bits of data is transmitted from the 12 data terminals 12DQs of the rank memory RANK0 to the 12 data terminals 12DQs of the memory controller 110. During a write operation of the rank memory RANK1, 288 bits of data is transmitted from the 12 data terminals 12DQs of the memory controller 110 to the 12 data terminals 12DQs of the rank memory RANK1.

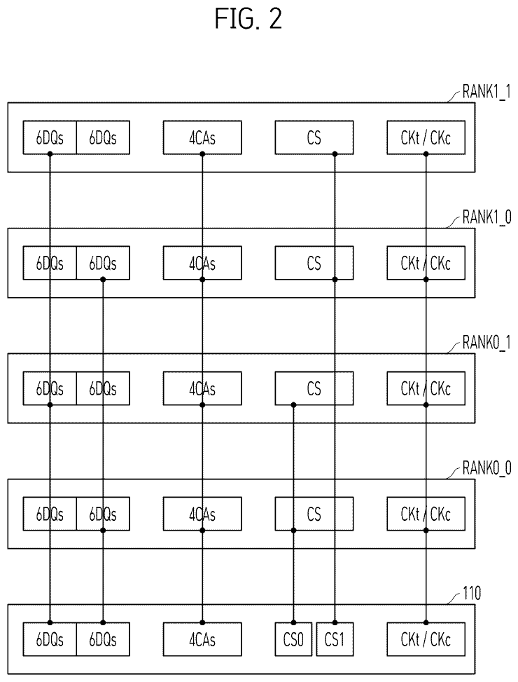

FIG. 2 is a diagram illustrating a connection between a memory controller 110 and memories RANK0_0, RANK0_1, RANK1_0, and RANK1_1 in a memory system in accordance with an embodiment of the present disclosure. In FIG. 2, the 12 data terminals of each of the memory controller 110 and the memories RANK0_0, RANK0_1, RANK1_0, and RANK1_1 are not indicated as 12DQs but as two 6DQs.

Referring to FIG. 2, the rank RANK0 of FIG. 1 includes two memories RANK0_O and RANK0_1, and the rank RANK1 of FIG. 1 includes two memories RANK1_0 and RANK1_1. That is, the memory controller 110 is connected to four memories RANK0_0, RANK0_1, RANK1_0, and RANK1_1. By configuring one rank with two memories, a storage capacity per rank can be increased.

In an embodiment, for each of the two memories in one rank, only six data terminals 6DQs among twelve data terminals 12DQs are connected to the memory controller 110. That is, among the 12 data terminals of the memory controller 110, six data terminals 6DQs are connected to the memory RANK0_0 of the rank RANK0 and the memory RANK1_0 of the rank RANK1, and the remaining six data terminals 6DQs are connected to the memory RANK0_1 of the rank RANK0 and the memory RANK1_1 of the rank RANK1.

In an embodiment, the remaining terminals 4CAs, CS0, CS1, CKt, and CKc of the memory controller 110 are connected to the memories RANK0_0, RANK0_1, RANK1_0, and RANK1_1 in the same manner as in FIG. 1. The memory controller 110 selects the memories RANK0_0 and RANK0_1 by using the chip select terminal CS0 or selects the memories RANK1_0 and RANK1_1 by using the chip select terminal CS1. Memories of the same rank operate at the same time.

In an embodiment, because only six data terminals 6DQs rather than 12 data terminals are used in each of the memories RANK0_0, RANK0_1, RANK1_0, and RANK1_1, the burst length BL is doubled and set to 48.

In an embodiment, during a read operation of the rank RANK0, 288 (=6*48) bits of data is transmitted to the memory controller 110 through the six data terminals 6DQs of the memory RANK0_0, and 288 bits of data is transmitted to the memory controller 110 through the six data terminals 6DQs of the memory RANK0_1. That is, during the read operation of the rank RANK0, a total of 572 bits of data is transmitted from the memories RANK0_0 and RANK0_1 to the memory controller 110. During a write operation of the rank RANK0, 288 bits of data is transmitted from the memory controller 110 to the memory RANK0_0, and 288 bits of data is transmitted from the memory controller 110 to the memory RANK0_1.

In an embodiment, during a read operation of the rank RANK1, 288 bits of data is transmitted to the memory controller 110 through the six data terminals 6DQs of the memory RANK1_0, and 288 bits of data is transmitted to the memory controller 110 through the six data terminals 6DQs of the memory RANK1_1. That is, during the read operation of the rank 1, a total of 572 bits of data is transmitted from the memories RANK1_0 and RANK1_1 to the memory controller 110. During a write operation of the rank 1, 288 bits of data is transmitted from the memory controller 110 to the memory RANK1_0, and 288 bits of data is transmitted from the memory controller 110 to the memory RANK1_1.

In an embodiment, the number of terminals, the number of data bits, and the like illustrated in FIGS. 1 and 2 are only examples and naturally vary depending on the design.

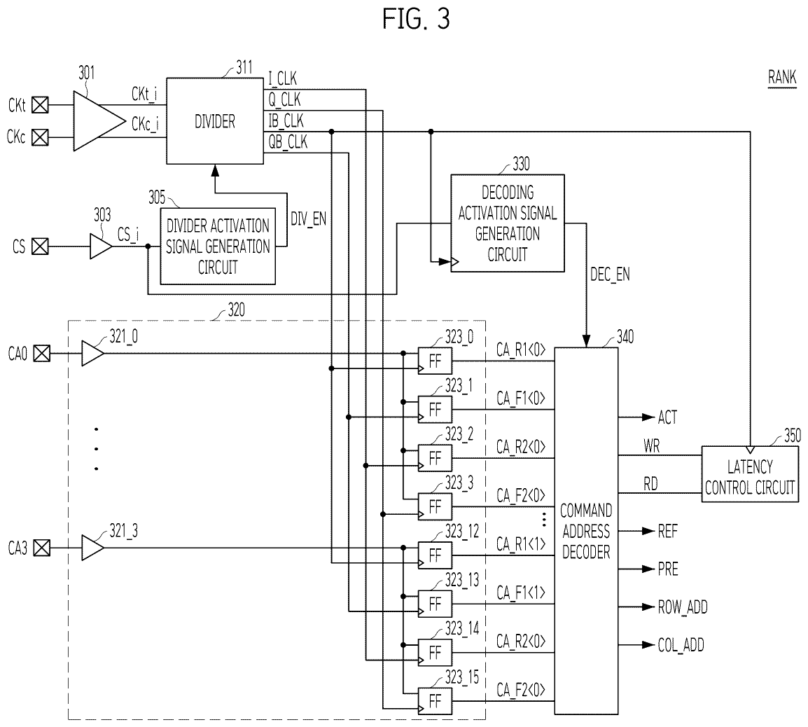

FIG. 3 is a configuration diagram of a memory RANK in accordance with an embodiment of the present disclosure. In an embodiment, the memory RANK in FIG. 3 is connected to the memory controller 110 as illustrated in FIG. 1 or is connected to the memory controller 110 as illustrated in FIG. 2. FIG. 3 illustrates parts related to receiving clocks, chip select signals, and command address signals from the memory RANK.

Referring to FIG. 3, the memory RANK includes clock terminals CKt and CKc, a chip select terminal CS, command address terminals CA0 to CA3, a clock receiver 301, a divider 311, a chip select signal receiver 303, a divider activation signal generation circuit 305, a command address reception circuit 320, a decoding activation signal generation circuit 330, a command address decoder 340, and a latency control circuit 350.

In an embodiment, the clock receiver 301 receives clocks CKt_i and CKc_i differentially input through the clock terminals CKt and CKc. The divider 311 generates divided 4-phase clocks I_CLK, Q_CLK, IB_CLK, and QB_CLK by dividing the clocks CKt_i and CKc_i received through the clock receiver 301. The divided 4-phase clocks I_CLK, Q_CLK, IB_CLK, and QB_CLK have a frequency of ½ of the clocks CKt_i and CKc_i received through the clock terminals CKt and CKc. Two clocks of the divided 4-phase clocks I_CLK, Q_CLK, IB_CLK, and QB_CLK have a phase difference of 90° therebetween: 1) two clocks I_CLK and Q_CLK have a phase difference of 90°, 2) two clocks IB_CLK and QB_CLK have a phase difference of 90°, 3) two clocks I_CLK and QB_CLK have a phase difference of 90°, and 4) two clocks Q_CLK and IB_CLK have a phase difference of 90°. The clock IB_CLK is an inversion of the clock I_CLK, and the clocks I_CLK and IB_CLK have a phase difference of 180°. The clock QB_CLK is an inversion of the clock Q_CLK, and the clocks Q_CLK and QB_CLK have a phase difference of 180°. FIG. 3 illustrates that 4-phase clocks are used in the memory RANK, but various multi-phase clocks such as 2-phase clocks and 8-phase clocks may be used depending on the memory RANK.

In an embodiment, the chip select signal receiver 303 receives a chip select signal CS_i input to the chip select terminal CS. The divider activation signal generation circuit 305 generates a divider activation signal DIV_EN by using the chip select signal CS_i received by the chip select signal receiver 303. When the chip select signal CS_i is activated once, the divider activation signal generation circuit 305 activates the divider activation signal DIV_EN. The divider 311 is activated in response to the activation of the divider activation signal DIV_EN, and continuously maintains the activated state after activation.

In an embodiment, the decoding activation signal generation circuit 330 generates a decoding activation signal DEC_EN for activating the command address decoder 340 by using the chip select signal CS_i received by the chip select signal receiver 303. The decoding activation signal generation circuit 330 detects the level of the chip select signal CS_i at a rising edge of the divided 4-phase clock IB_CLK, and outputs the detection result as the decoding activation signal DEC_EN.

In an embodiment, the command address reception circuit 320 receives command address signals input to the command address terminals CA0 to CA3 by using the divided 4-phase clocks I_CLK, Q_CLK, IB_CLK, and QB_CLK. The command address reception circuit 320 includes command address receivers 321_0 to 321_3 and flip-flops 323_0 to 323_15.

In an embodiment, the command address receivers 321_0 to 321_3 receive signals from the command address terminals CA0 to CA3. The flip-flops 323_0 to 323_15 latch the reception results of the command address receivers 321_0 to 321_3 by using the divided 4-phase clocks I_CLK, Q_CLK, IB_CLK, and QB_CLK. Because the four clocks I_CLK, Q_CLK, IB_CLK, and QB_CLK are used, the command address receivers 321_0 to 321_3 and the flip-flops 323_0 to 323_15 correspond in a 1:4 ratio. That is, one of the command address receivers 321_0 to 321_3 is connected to four of the flip-flops 323_0 to 323_15. For example, the flip-flops 323_0 to 323_3 latch is connected to the command address receiver 321_0. The flip-flops 323_0 to 323_3 latch the reception result of the command address receiver 321_0 at the rising edges of the divided 4-phase clocks I_CLK, Q_CLK, IB_CLK, and QB_CLK. Likewise, the flip-flops 323_12 to 323_15 latch the reception result of the command address receiver 321_3 at the rising edges of the divided 4-phase clocks I_CLK, Q_CLK, IB_CLK, and QB_CLK.

In an embodiment, the command address decoder 340 decodes signals CA_R1<0:3>, CA_F1<0:3>, CA_R2<0:3>, and CA_F2<0:3> latched by the flip-flops 323_0 to 323_15 of the command address reception circuit 320 to generate internal command signals ACT, WR, RD, REF, and PRE and internal address signals ROW_ADD and COL_ADD. An active signal ACT is an internal command signal for performing an active operation. A write signal WR is an internal command signal for performing a write operation. A read signal RD is an internal command signal for performing a read operation. A refresh signal REF is an internal command signal for performing a refresh operation. A precharge signal PRE is an internal command signal for performing a precharge operation. A row address signal ROW_ADD is an address signal for selecting a row, and a column address signal COL_ADD is an address signal for selecting a column.

In an embodiment, the latency control circuit 350 operates in synchronization with one clock IB_CLK of the divided 4-phase clocks I_CLK, Q_CLK, IB_CLK, and QB_CLK and performs a latency control operation. The latency control operation means control of write latency WL during a write operation, control of read latency RL during a read operation, and the like.

Referring again to FIGS. 1 and 2, in the connection structure as illustrated in FIG. 1, because the two memory chips RANK0 and RANK1 are connected to one memory controller 110, there is no particular concern with loading of lines. However, in the connection structure as illustrated in FIG. 2, because the four memory chips RANK0_0, RANK0_1, RANK1_0, and RANK1_1 are connected to one memory controller 110, loading of lines is a concern. In particular, the loading of the command address terminals 4CAs and the clock terminals CKt and CKc of the four memory chips RANK0_0, RANK0_1, RANK1_0, and RANK1_1, which are commonly connected to the memory controller 110, is a concern. Since the clock transmitted to the clock terminals CKt and CKc uses differential signaling and is a signal that regularly repeats a logic high level and a logic low level, relatively stable transmission is possible even though loading increases. However, because the command address signals transmitted to the command address terminals 4CAs use single ended signaling and are signals having irregular logic high and low levels, signal quality deterioration due to an increase in loading is relatively large. That is, in the connection relationship as illustrated in FIG. 2, stable transmission and reception of command address signals is difficult.

In order to cope with such a concern, when the memory chips and the memory controller are connected as illustrated in FIG. 2, a command address half rate mode is proposed to reduce the rate of command address signals by half compared to the connection structure as illustrated in FIG. 1.

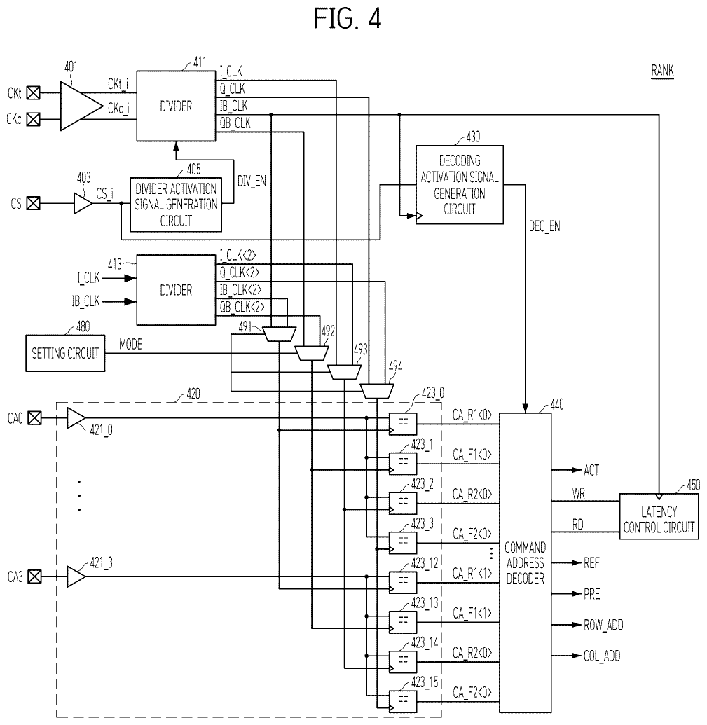

FIG. 4 is a configuration diagram of a memory RANK in accordance with another embodiment of the present disclosure. In an embodiment, the memory RANK of FIG. 4 is connected to the memory controller 110 as illustrated in FIG. 1, and is also connected to the memory controller 110 as illustrated in FIG. 2. FIG. 4 illustrates parts related to receiving clocks, chip select signals, and command address signals from the memory RANK. The memory RANK of FIG. 4 supports an operation in a command address half rate mode.

Referring to FIG. 4, the memory RANK includes clock terminals CKt and CKc, a chip select terminal CS, command address terminals CA0 to CA3, a clock receiver 401, dividers 411 and 413, a chip select signal receiver 403, a divider activation signal generation circuit 405, a setting circuit 480, selectors 491 to 494, a command address reception circuit 420, a decoding activation signal generation circuit 430, a command address decoder 440, and a latency control circuit 450.

In an embodiment, the clock receiver 401 receives clocks CKt_i and CKc_i differentially input through the clock terminals CKt and CKc. The divider 411 generates divided 4-phase clocks I_CLK, Q_CLK, IB_CLK, and QB_CLK by dividing the clocks CKt_i and CKc_i received through the clock receiver 401. The divided 4-phase clocks I_CLK, Q_CLK, IB_CLK, and QB_CLK have a frequency of ½ of the clock CKt_i and CKc_i received through the clock terminals CKt and CKc. Two clocks of the divided 4-phase clocks I_CLK, Q_CLK, IB_CLK, and QB_CLK have a phase difference of 90° therebetween: 1) two clocks I_CLK and Q_CLK have a phase difference of 90°, 2) two clocks IB_CLK and QB_CLK have a phase difference of 90°, 3) two clocks I_CLK and QB_CLK have a phase difference of 90°, and 4) two clocks Q_CLK and IB_CLK have a phase difference of 90°. The clock IB_CLK is an inversion of the clock I_CLK, and the clocks I_CLK and IB_CLK have a phase difference of 180°. The clock QB_CLK is an inversion of the clock Q_CLK, and the clocks Q_CLK and QB_CLK have a phase difference of 180°.

In an embodiment, the divider 413 redivides the division result of the divider 411 and generates redivided 4-phase clocks I_CLK(2), Q_CLK(2), IB_CLK(2), and QB_CLK(2). The divider 413 divides the clocks I_CLK and IB_CLK among the 4-phase clocks I_CLK, Q_CLK, IB_CLK, and QB_CLK generated by the divider 411, and generates the redivided 4-phase clocks I_CLK(2), Q_CLK(2), IB_CLK(2), and QB_CLK(2). The redivided 4-phase clocks I_CLK(2), Q_CLK(2), IB_CLK(2), and QB_CLK(2) have a frequency of ½ of the divided 4-phase clocks I_CLK, Q_CLK, IB_CLK, and QB_CLK. Two clocks of the 4-phase clocks I_CLK(2), Q_CLK(2), IB_CLK(2), and QB_CLK(2) have a phase difference of 90°: 1) two clocks I_CLK(2) and Q_CLK(2) have a phase difference of 90°, 2) two clocks IB_CLK(2) and QB_CLK(2) have a phase difference of 90°, 3) two clocks I_CLK(2) and QB_CLK(2) have a phase difference of 90°, and 4) two clocks Q_CLK(2) and IB_CLK(2) have a phase difference of 90°. The clock IB_CLK(2) is an inversion of the clock I_CLK(2), and the clocks I_CLK(2) and IB_CLK(2) have a phase difference of 180°. The clock QB_CLK(2) is an inversion of the clock Q_CLK(2), and the clocks Q_CLK(2) and QB_CLK(2) have a phase difference of 180°.

In an embodiment, the chip select signal receiver 403 receives a chip select signal CS_i input to the chip select terminal CS. The divider activation signal generation circuit 405 generates a divider activation signal DIV_EN by using the chip select signal CS_i received by the chip select signal receiver 303. When the chip select signal CS_i is activated once, the divider activation signal generation circuit 405 activates the divider activation signal DIV_EN. The dividers 411 and 413 are activated in response to the activation of the divider activation signal DIV_EN, and continuously maintain the activated state after activation. Because the divider activation signal generation circuit 405 is used to reduce current consumption of the dividers 411 and 413, it is omitted depending on the design.

In an embodiment, the decoding activation signal generation circuit 430 generates a decoding activation signal DEC_EN for activating the command address decoder 440 by using the chip select signal CS_i received by the chip select signal receiver 403. The decoding activation signal generation circuit 430 detects the level of the chip select signal CS_i at a rising edge of the divided 4-phase clock IB_CLK, and outputs the detection result as the decoding activation signal DEC_EN.

In an embodiment, the setting circuit 480 is a circuit for setting the operation mode of the memory RANK. The setting circuit 480 sets the command address half rate mode. When the memory RANK is connected to the memory controller 110 as illustrated in FIG. 1, the command address half rate mode is not set. When the memory RANK is connected to the memory controller 110 as illustrated in FIG. 2, the command address half rate mode is set. A mode signal MODE is activated when the command address half rate mode is set, and is deactivated otherwise.

When the mode signal MODE is deactivated, the selectors 491 to 494 select the 4-phase clocks I_CLK, Q_CLK, IB_CLK, and QB_CLK generated by the divider 411 and transmit the selected clocks to the command address reception circuit 420. When the mode signal MODE is activated, the selectors 491 to 494 select the 4-phase clocks I_CLK(2), Q_CLK(2), IB_CLK(2), and QB_CLK(2) generated by the divider 413 and transmit the selected clocks I, Q, IB, and QB to the command address reception circuit 420.

In an embodiment, the command address reception circuit 420 receives command address signals, which are input to the command address terminals CA0 to CA3, by using the clocks selected by the selectors 491 to 494. The command address reception circuit 420 includes command address receivers 421_0 to 421_3 and flip-flops (FF) 423_0 to 423_15.

In an embodiment, the command address receivers 421_0 to 421_3 receive signals from the command address terminals CA0 to CA3. The flip-flops 423_0 to 423_15 latch the reception results of the command address receivers 421_0 to 421_3 by using clocks I, Q, IB, and QB selected by the selectors 491 to 494. Because the four clocks I, Q, IB, and QB are used, the command address receivers 421_0 to 421_3 and the flip-flops 423_0 to 423_15 correspond in a 1:4 ratio. The flip-flops 423_0 to 423_3 latch the reception result of the command address receiver 421_0 at the rising edges of the clocks I, Q, IB, and QB. Likewise, the flip-flops 423_12 to 423_15 latch the reception result of the command address receiver 421_3 at the rising edges of the clocks I, Q, IB, and QB.

In an embodiment, the command address decoder 440 decodes signals CA_R1<0:3>, CA_F1<0:3>, CA_R2<0:3>, and CA_F2<0:3> latched by the flip-flops 423_0 to 423_15 of the command address reception circuit 420 to generate internal command signals ACT, WR, RD, REF, and PRE and internal address signals ROW_ADD and COL_ADD. An active signal ACT is an internal command signal for performing an active operation. A write signal WR is an internal command signal for performing a write operation. A read signal RD is an internal command signal for performing a read operation. A refresh signal REF is an internal command signal for performing a refresh operation. A precharge signal PRE is an internal command signal for performing a precharge operation. A row address signal ROW_ADD is an address signal for selecting a row, and a column address signal COL_ADD is an address signal for selecting a column.

In an embodiment, the latency control circuit 450 operates in synchronization with one clock IB_CLK of the divided 4-phase clocks I_CLK, Q_CLK, IB_CLK, and QB_CLK and performs a latency control operation. The latency control operation means control of write latency WL during a write operation, control of read latency RL during a read operation, and the like.

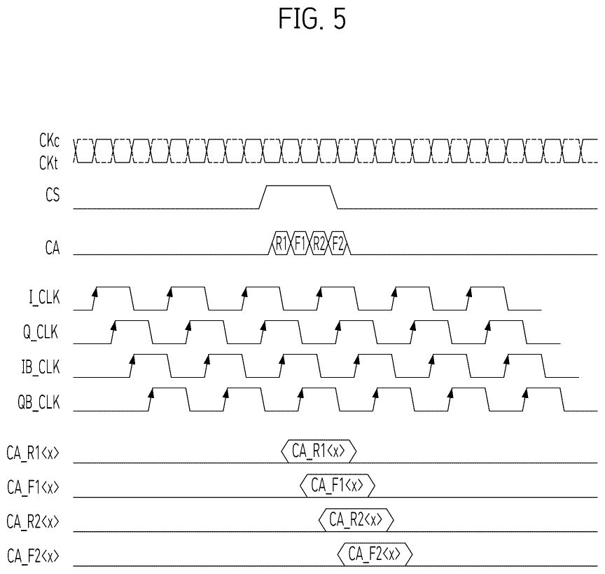

FIG. 5 is a timing diagram illustrating an operation when the memory RANK of FIG. 4 is connected to the memory controller 110 in the same manner as in FIG. 1 and the command address half rate mode is not set in accordance with an embodiment of the present disclosure.

Referring to FIG. 5, a signal of the chip select terminal CS is activated at a logic high level. In a duration where the signal of the chip select terminal CS is activated at a logic high level, command address signals R1, F1, R2, and F2 are consecutively applied to the command address terminals CA_x (indicating CA0 to CA3). It can be seen that two of the command address signals R1, F1, R2, and F2 are input per clock cycle of the clock terminals CKt and CKc.

In an embodiment, because the command address half rate mode is not set, the command address reception circuit 420 receives the command address signals R1, F1, R2, and F2 by using the 4-phase clocks I_CLK, Q_CLK, IB_CLK, and QB_CLK generated by the divider 411. That is, the flip-flops 423_0 to 423_15 latch the command address signals R1, F1, R2, and F2 at the rising edges of the 4-phase clocks I_CLK, Q_CLK, IB_CLK, and QB_CLK generated by the divider 411. As a result, signals CA_R1<x>, CA_F1<x>, CA_R2<x>, and CA_F2<x> are generated.

In an embodiment, the signals CA_R1<x>, CA_F1<x>, CA_R2<x>, and CA_F2<x> are transmitted to the command address decoder 440 and are decoded by the command address decoder 440.

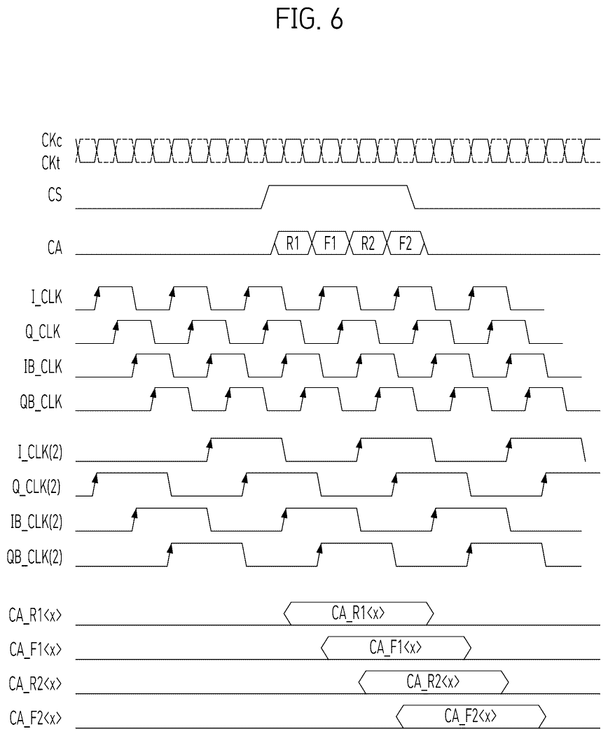

FIG. 6 is a timing diagram illustrating an operation when the memory RANK of FIG. 4 is connected to the memory controller 110 in the same manner as in FIG. 2 and the command address half rate mode is set in accordance with an embodiment of the present disclosure.

Referring to FIG. 6, a signal of the chip select terminal CS is activated at a logic high level. In a duration where the signal of the chip select terminal CS is activated at a logic high level, command address signals R1, F1, R2, and F2 are consecutively applied to the command address terminals CA_x. It can be seen that one of the command address signals R1, F1, R2, and F2 is input per clock cycle of the clock terminals CKt and CKc. That is, it can be seen that the frequency of the command address signals R1, F1, R2, and F2 in FIG. 6 is a half of the frequency of the command signals R1, F1, R2, and F2 in FIG. 5.

Since the command address half rate mode is set, the command address reception circuit 420 receives the command address signals R1, F1, R2, and F2 by using the 4-phase clocks I_CLK(2), Q_CLK(2), IB_CLK(2), and QB_CLK(2) generated by the divider 413. That is, the flip-flops 423_0 to 423_15 latch the command address signals R1, F1, R2, and F2 at the rising edges of the 4-phase clocks I_CLK(2), Q_CLK(2), IB_CLK(2), and QB_CLK(2) generated by the divider 413. As a result, signals CA_R1<x>, CA_F1<x>, CA_R2<x>, and CA_F2<x> are generated.

In an embodiment, the signals CA_R1<x>, CA_F1<x>, CA_R2<x>, and CA_F2<x> are transmitted to the command address decoder 440 and are decoded by the command address decoder 440.

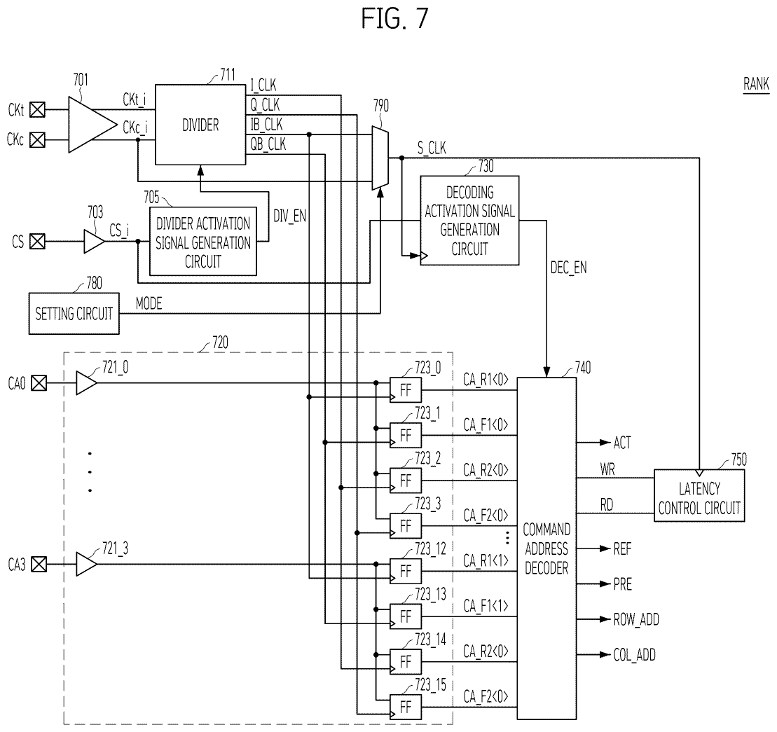

FIG. 7 is a configuration diagram of a memory RANK in accordance with yet another embodiment of the present disclosure. In an embodiment, the memory RANK of FIG. 7 is connected to the memory controller 110 as illustrated in FIG. 1, and is also connected to the memory controller 110 as illustrated in FIG. 2. FIG. 7 illustrates parts related to receiving clocks, chip select signals, and command address signals from the memory RANK. The memory RANK of FIG. 7 supports an operation in the command address half rate mode. FIGS. 4 and 6 illustrate that the signals of the command address terminals CA0 to CA3 are applied at a half rate when the command address half rate mode is set; however, in FIG. 7, when the command address half rate mode is set, not only the signals of the command address terminals CA0 to CA3, but also the clocks input to the clock terminals CKt and CKc are applied at a half rate.

Referring to FIG. 7, the memory RANK includes clock terminals CKt and CKc, a chip select terminal CS, command address terminals CA0 to CA3, a clock receiver 701, a divider 711, a chip select signal receiver 703, a divider activation signal generation circuit 705, a setting circuit 780, a selector 790, a command address reception circuit 720, a decoding activation signal generation circuit 730, a command address decoder 740, and a latency control circuit 750.

In an embodiment, the clock receiver 701 receives clocks CKt_i and CKc_i differentially input through the clock terminals CKt and CKc. The divider 711 generate 4-phase clocks I_CLK, Q_CLK, IB_CLK, and QB_CLK by dividing the clocks CKt_i and CKc_i received through the clock receiver 701. The 4-phase clocks I_CLK, Q_CLK, IB_CLK, and QB_CLK have a frequency of ½ of the clocks CKt_i and CKc_i received through the clock terminals CKt and CKc. Two clocks of the divided 4-phase clocks I_CLK, Q_CLK, IB_CLK, and QB_CLK have a phase difference of 90° therebetween: 1) two clocks I_CLK and Q_CLK have a phase difference of 90°, 2) two clocks IB_CLK and QB_CLK have a phase difference of 90°, 3) two clocks I_CLK and QB_CLK have a phase difference of 90°, and 4) two clocks Q_CLK and IB_CLK have a phase difference of 90°. The clock IB_CLK is an inversion of the clock I_CLK, and the clocks I_CLK and IB_CLK have a phase difference of 180°. The clock QB_CLK is an inversion of the clock Q_CLK, and the clocks Q_CLK and QB_CLK have a phase difference of 180°.

In an embodiment, the chip select signal receiver 703 receives a chip select signal CS_i input to the chip select terminal CS. The divider activation signal generation circuit 705 generates a divider activation signal DIV_EN by using the chip select signal CS_i received by the chip select signal receiver 703. When the chip select signal CS_i is activated once, the divider activation signal generation circuit 705 activates the divider activation signal DIV_EN. The divider 711 is activated in response to the activation of the divider activation signal DIV_EN, and continuously maintains the activated state after activation. Because the divider activation signal generation circuit 705 is used to reduce current consumption of the divider 711, it is omitted depending on the design.

In an embodiment, the setting circuit 780 sets the operation mode of the memory RANK. The setting circuit 780 sets the command address half rate mode. When the memory RANK is connected to the memory controller 110 as illustrated in FIG. 1, the command address half rate mode is not set. When the memory RANK is connected to the memory controller 110 as illustrated in FIG. 2, the command address half rate mode is set. A mode signal MODE is activated when the command address half rate mode is set, and is deactivated otherwise.

In an embodiment, the selector 790 selects the 4-phase clock IB_CLK generated by the divider 711 when the mode signal MODE is inactivated, and selects and outputs the clock CKc_i when the mode signal MODE is activated. Since the frequency of the clock input to the clock terminals CKt and CKc changes depending on the mode, the selector 790 is used to allow the frequency of the clock S_CLK used by the decoding activation signal generation circuit 730 and the latency control circuit 750 to be constantly maintained even though the mode changes.

In an embodiment, the decoding activation signal generation circuit 730 generates a decoding activation signal DEC_EN for activating the command address decoder 740 by using the chip select signal CS_i received by the chip select signal receiver 703. The decoding activation signal generation circuit 730 detects the level of the chip select signal CS at the rising edge of the clock S_CLK selected by the selector 790, and outputs the detection result as the decoding activation signal DEC_EN.

In an embodiment, the command address reception circuit 720 receives command address signals input to the command address terminals CA0 to CA3 by using the divided 4-phase clocks I_CLK, Q_CLK, IB_CLK, and QB_CLK. The frequency (or period) of the command address signals changes depending on the mode, but because the frequencies of the four phase clocks I_CLK, Q_CLK, IB_CLK, and QB_CLK also change depending on the mode, there is no concern in the operation of the command address reception circuit 720. The command address reception circuit 720 includes command address receivers 721_0 to 721_3 and flip-flops 723_0 to 723_15.

In an embodiment, the command address receivers 721_0 to 721_3 receive signals from the command address terminals CA0 to CA3. The flip-flops 723_0 to 723_15 latch the reception results of the command address receivers 721_0 to 721_3 by using the divided 4-phase clocks I_CLK, Q_CLK, IB_CLK, and QB_CLK. Because the four clocks I_CLK, Q_CLK, IB_CLK, and QB_CLK are used, the command address receivers 721_0 to 721_3 and the flip-flops 723_0 to 723_15 correspond in a 1:4 ratio. The flip-flops 723_0 to 723_3 latch the reception result of the command address receiver 721_0 at the rising edges of the divided 4-phase clocks I_CLK, Q_CLK, IB_CLK, and QB_CLK. Likewise, the flip-flops 723_12 to 723_15 latch the reception result of the command address receiver 721_3 at the rising edges of the divided 4-phase clocks I_CLK, Q_CLK, IB_CLK, and QB_CLK.

In an embodiment, the command address decoder 740 decodes signals CA_R1<0:3>, CA_F1<0:3>, CA_R2<0:3>, and CA_F2<0:3> latched by the flip-flops 723_0 to 723_15 of the command address reception circuit 720 to generate internal command signals ACT, WR, RD, REF, and PRE and internal address signals ROW_ADD and COL_ADD. An active signal ACT is an internal command signal for performing an active operation. A write signal WR is an internal command signal for performing a write operation. A read signal RD is an internal command signal for performing a read operation. A refresh signal REF is an internal command signal for performing a refresh operation. A precharge signal PRE is an internal command signal for performing a precharge operation. A row address signal ROW_ADD is an address signal for selecting a row, and a column address signal COL_ADD is an address signal for selecting a column.

In an embodiment, the latency control circuit 750 operates in synchronization with the clock S_CLK selected by the selector 790 and performs a latency control operation. The latency control operation may mean write latency control during a write operation, read latency control during a read operation, and the like.

Although the technical spirit of the present disclosure has been specifically described according to the above embodiments, it should be noted that the above embodiments are for description, not for limitation. Furthermore, those who skilled in the art will understand that various embodiments can be made within the scope of the technical spirit of the present disclosure. Moreover, the embodiments may be combined to form additional embodiments.

What is claimed is:

1. A memory comprising:
a clock receiver configured to receive clocks;
a first divider configured to divide the clocks to generate divided multi-phase clocks;
a second divider configured to redivide the divided multi-phase clocks to generate redivided multi-phase clocks; and
a command address reception circuit configured to receive a command and an address by using the divided multi-phase clocks in a first mode, and receive the command and the address by using the redivided multi-phase clocks in a second mode.

2. The memory of claim 1, wherein a frequency of the command and the address input to the memory in the first mode is twice a frequency of the command and the address input to the memory in the second mode.

3. The memory of claim 2, wherein, in the first mode, 2N data terminals of the memory, where N is an integer of 1 or more, are connected to a memory controller, and a burst length for data transmitted and received through the 2N data terminals is set to M, where M is an integer of 1 or more, and
in the second mode, N data terminals of the memory are connected to the memory controller and the burst length for data transmitted and received through the N data terminals is set to 2M.

4. The memory of claim 1, wherein the command address reception circuit comprises:
a plurality of command address receivers configured to receive signals from a plurality of command address terminals; and
a plurality of flip-flops configured to latch reception results of the command address receivers by using the divided multi-phase clocks in the first mode and by using the redivided multi-phase clocks in the second mode.

5. The memory of claim 4, wherein the divided multi-phase clocks and the redivided multi-phase clocks include 4-phase clocks, and
the plurality of command address receivers is connected to the plurality of flip-flops in a 1:4 ratio.

6. The memory of claim 1, further comprising:
a command address decoder configured to decode the command and the address received by the command address reception circuit to generate internal command signals and internal address signals.

7. The memory of claim 6, further comprising:
a latency control circuit configured to operate in synchronization with one of the divided multi-phase clocks and perform a latency control operation on at least one of read and write operations for the memory.

8. The memory of claim 6, further comprising:
a chip select signal receiver configured to receive a chip select signal from a chip select terminal; and
a decoding activation signal generation circuit configured to generate a decoding activation signal for activating the command address decoder by using the chip select signal.

9. A memory controller comprising:
a first clock terminal and a second clock terminal commonly connected to a first memory and a second memory in a first mode, and commonly connected to a third memory, a fourth memory, a fifth memory, and a sixth memory in a second mode;
a plurality of command address terminals commonly connected to the first memory and the second memory in the first mode to output command address signals at a first frequency, and commonly connected to the third memory, the fourth memory, the fifth memory, and the sixth memory in the second mode to output the command address signals at a second frequency being a half of the first frequency;
a first chip select terminal connected to the first memory in the first mode, and commonly connected to the third memory and the fourth memory in the second mode;
a second chip select terminal connected to the second memory in the first mode, and commonly connected to the fifth memory and the sixth memory in the second mode;
a plurality of first data terminals commonly connected to the first memory and the second memory in the first mode, and commonly connected to the third memory and the fifth memory in the second mode; and
a plurality of second data terminals commonly connected to the first memory and the second memory in the first mode, and commonly connected to the fourth memory and the sixth memory in the second mode.

10. The memory controller of claim 9, wherein, in the first mode, during one write operation, M bits of data, where M is an integer of 1 or more, is consecutively output to the first and second memories from each of the plurality of first data terminals and the plurality of second data terminals, and
in the second mode, during one write operation, 2M bits of data is consecutively output to the third, fourth, fifth and sixth memories from each of the plurality of first data terminals and the plurality of second data terminals.

11. The memory controller of claim 9, wherein, in the first mode, a clock of a third frequency is output to the first clock terminal and the second clock terminal, and
in the second mode, a clock of a fourth frequency being a half of the third frequency is output to the first clock terminal and the second clock terminal.

12. A memory comprising:
a clock receiver configured to receive clocks;
a divider configured to divide the clocks to generate divided multi-phase clocks;
a command address reception circuit configured to receive a command and an address by using the divided multi-phase clocks;
a command address decoder configured to decode the command and the address received by the command address reception circuit to generate internal command signals and internal address signals; and
a latency control circuit configured to perform a latency control operation on at least one of read and write operations, in synchronization with one of the divided multi-phase clocks in a first mode, and perform the latency control operation in synchronization with the clocks in a second mode.

13. The memory of claim 12, wherein a frequency of the command and the address input to the memory in the first mode is twice a frequency of the command and the address input to the memory in the second mode, and
a frequency of the clocks input to the memory in the first mode is twice a frequency of the clocks input to the memory in the second mode.

14. The memory of claim 13, wherein, in the first mode, 2N data terminals of the memory, where N is an integer of 1 or more, are connected to a memory controller and a burst length for data transmitted and received through the 2N data terminals is set to M, where M is an integer of 1 or more, and
in the second mode, N data terminals of the memory are connected to the memory controller and the burst length for data transmitted and received through the N data terminals is set to 2M.

15. The memory of claim 12, further comprising:
a chip select signal receiver configured to receive a signal from a chip select terminal; and
a decoding activation signal generation circuit configured to generate a decoding activation signal for activating the command address decoder by using the chip select signal in synchronization with one of the divided multi-phase clocks in the first mode, and generate a decoding activation signal for activating the command address decoder by using the chip select signal in synchronization with the clocks in the second mode.

16. The memory of claim 12, wherein the command address reception circuit comprises:
a plurality of command address receivers configured to receive signals from a plurality of command address terminals; and
a plurality of flip-flops configured to latch reception results of the command address receivers by using the divided multi-phase clocks.

17. The memory of claim 16, wherein the divided multi-phase clocks include 4-phase clocks, and the plurality of command address receivers is connected to the plurality of flip-flops in a 1:4 ratio.

18. The memory of claim 7, wherein the latency control circuit performs the latency control operation based on the internal command signals and the internal address signals.

19. The memory of claim 12, wherein the latency control circuit performs the latency control operation based on the internal command signals and the internal address signals.
